(19) United States
(12) Patent Application Publication
(10) Pub. No.: US 2025/0314813 A1
(43) Pub. Date: Oct. 9, 2025

(54) OPTICAL MEMBER AND OPTICAL DISPLAY APPARATUS COMPRISING THE SAME

(71) Applicant: SAMSUNG SDI CO., LTD., Yongin-si (KR)

(72) Inventors: Irina NAM, Suwon-si (KR); Dong Heon YUN, Suwon-si (KR); Won KIM, Suwon-si (KR); Il Jin KIM, Suwon-si (KR)

(21) Appl. No.: 19/096,419

(22) Filed: Mar. 31, 2025

(30) Foreign Application Priority Data
Apr. 3, 2024 (KR) 10-2024-0045103

(51) Int. Cl. G02B 5/20

(52) U.S. Cl. CPC G02B 5/208

(57) ABSTRACT

An optical member and an optical display apparatus are disclosed. An optical member includes an adhesive layer and a base film stacked on a surface of the adhesive layer, and the adhesive layer includes a cured product of a composition including a UV absorbent and a (meth)acrylic copolymer, and the optical member has a light transmittance variation ΔT of 0%, as calculated according to Equation 1, and a color value variation Δb* of less than 0.4, as calculated according to Equation 2.

### CROSS-REFERENCE TO RELATED APPLICATION

The present application claims priority to and the benefit of Korean Patent Application No. 10-2024-0045103, filed on Apr. 3, 2024 in the Korean Intellectual Property Office, the entire disclosure of which is incorporated herein by reference.

### BACKGROUND

### 1. Field

Aspects of embodiments of the present invention relate to an optical member and an optical display apparatus including the same.

### 2. Description of the Related Art

Light emitting displays including organic light emitting displays and the like are not required to include a polarizing plate. However, external light entering a light emitting display may be subjected to total reflection in a panel within the light emitting display, causing deterioration in screen quality. Accordingly, the light emitting display is generally provided with a polarizing plate on an upper surface of a display panel. The polarizing plate may include a polarizer and a retardation film. The polarizing plate may contain a UV absorbent to prevent or reduce external light from causing damage to light emitting devices.

With a recent trend toward a reduction in thickness of optical displays, POL-LESS optical displays (polarizing plate-free optical displays) have been developed in the art. In these polarizing plate-free displays, light emitting devices may inevitably be exposed to external light and can be easily damaged thereby.

The background technique of the present invention is disclosed in Japanese Unexamined Patent Publication No. 2015-010192.

### SUMMARY

According to an aspect of one or more embodiments of the present invention, an optical member having a low light transmittance variation at a wavelength of 380 nm, even if exposed to UV light for a long period of time under repeated temperature changes between room temperature and high temperature, is provided.

According to another aspect of one or more embodiments of the present invention, an optical member that has a low variation of color value b*, even if exposed to UV light for a long period of time under repeated temperature changes between room temperature and high temperature, is provided.

According to another aspect of one or more embodiments of the present invention, an optical member that has excellent durability and high peel strength with respect to an optical display panel is provided.

According to an aspect of one or more embodiments of the present invention, an optical member is provided.

According to one or more embodiments, an optical member includes an adhesive layer and a base film stacked on a surface of the adhesive layer, wherein the adhesive layer includes a cured product of a composition including a UV absorbent and a (meth)acrylic copolymer, and wherein the optical member has a light transmittance variation ΔT of 0%, as calculated according to the following Equation 1, and a color value variation Δb* of less than 0.4, as calculated according to the following Equation 2:

$$Δ T = \vert {T}_{2} - {T}_{1} \vert , \qquad Equation 1$$

where T₁ is light transmittance (unit: %) of the optical member, as measured at a wavelength of 380 nm, and T₂ is light transmittance (unit: %) of the optical member, as measured at a wavelength of 380 nm after total 21 cycles of light irradiation, each of the cycles being defined as irradiating the optical member with light at a wavelength of 340 nm and at an irradiance of 0.35 W/m² while the optical member is left at 25° C. for 4 hours and then left at 63° C. for 8 hours;

$$Δ b *= \vert ( {b}_{2}^{⋆} ) - ( {b}_{1}^{⋆} ) \vert , \qquad Equation 2$$

where (b*₁) is a color value b* of the optical member, and (b*₂) is a color value b* of the optical member, as measured after a total of 21 cycles of light irradiation, each of the cycles being defined as irradiating the optical member with light at a wavelength of 340 nm and at an irradiance of 0.35 W/m² while the optical member is left at 25° C. for 4 hours and then left at 63° C. for 8 hours.

According to another aspect of the present invention, an optical display apparatus is provided.

The optical display apparatus includes the optical member according to an embodiment.

According to an aspect, embodiments of the present invention provide an optical member having a low light transmittance variation at a wavelength of 380 nm, even if exposed to UV light for a long period of time under repeated temperature changes between room temperature and high temperature.

According to another aspect, embodiments of the present invention provide an optical member that has a low variation of color value b* even if exposed to UV light for a long period of time under repeated temperature changes between room temperature and high temperature.

According to another aspect, embodiments of the present invention provide an optical member that has excellent durability and high peel strength with respect to an optical display panel.

### DETAILED DESCRIPTION

Herein, some example embodiments of the present invention will be described in further detail with reference to the accompanying drawings such that the present invention may be easily implemented by a person having ordinary knowledge in the art. However, it is to be understood that the present invention may be embodied in different ways and is not limited to the following described embodiments.

The terminology used herein is for the purpose of describing example embodiments and is not intended to limit the present invention. Herein, the singular forms “a,” “an,” and “the” are intended to include the plural forms as well, unless the context specifically indicates otherwise.

Herein, “homopolymer glass transition temperature” may refer to a glass transition temperature (Tg) measured on a homopolymer of a target monomer using a DSC Discovery (TA Instruments). The homopolymer of the target monomer is heated to 180° C. at a heating rate of 20° C./min, is slowly cooled to −100° C., and is heated again to 100° C. at a heating rate of 10° C./min to obtain data of an endothermic transition curve. An inflection point of the endothermic transition curve may be defined as the glass transition temperature of the target monomer in a homopolymer phase.

Herein, “light transmittance” refers to total light transmittance.

Herein, “b* value” refers to a color value measured in accordance with the International Commission on Illumination (CIE).

Herein, “light emitting device” may refer to an organic or inorganic light emitting device and may include a device, such as a light emitting diode (LED), an organic light emitting diode (OLED), a quantum dot light emitting diode (QLED), a light emitting material a phosphor, and the like.

Herein, “(meth)acryl” refers to acryl and/or methacryl.

As used herein to represent a specific numerical range, “X to Y” means “greater than or equal to X and less than or equal to Y (X≤ and ≤Y)”.

According to one or more embodiments, an optical member according to the present invention may be applied to an optical display apparatus, for example, a light emitting device display, which does not include a polarizing plate including a polarizer. By replacing the polarizing plate, the optical member can resolve a phenomenon that the light emitting device is damaged by external light, causing reduction in lifespan of the light emitting device display.

According to one or more embodiments, the optical member has a low light transmittance variation at a wavelength of 380 nm, even if exposed to UV light for a long period of time under repeated temperature changes between room temperature and high temperature. As such, damage to the light emitting device by external light may be prevented or substantially prevented, even if the light emitting device is exposed to UV light for a long period of time under repeated temperature changes between room temperature and high temperatures.

In this regard, the optical member has a light transmittance variation ΔT of 0%, as calculated according to the following Equation 1. Within this range, the light emitting device can have improved lifespan due to less damage, even if exposed to UV light for a long period of time:

$$Δ T = \vert {T}_{2} - {T}_{1} \vert , \qquad Equation 1$$

where T₁ is light transmittance (unit: %) of the optical member, as measured at a wavelength of 380 nm, and T₂ is light transmittance (unit: %) of the optical member, as measured at a wavelength of 380 nm after a total of 21 cycles of light irradiation, each cycle being defined as irradiating the optical member with light at a wavelength of 340 nm and at an irradiance of 0.35 W/m² while the optical member is left at 25° C. for 4 hours and then left at 63° C. for 8 hours.

In one or more embodiments, in Equation 1, T₁ may be 0.05% or less, for example, 0.04% or less, or 0 to 0.04%.

In one or more embodiments, in Equation 1, T₂ may be 0.05% or less, for example, 0.04% or less, or 0 to 0.04%.

According to one or more embodiments, the optical member has a low variation of color value b*, even if exposed to UV light for a long period of time under repeated temperature changes between room temperature and high temperature. This means that the optical member does not undergo increase in color value b*, even if exposed to UV light for a long period of time under repeated temperature changes between room temperature and high temperature, thereby preventing or substantially preventing change or deterioration in screen quality even after the optical member is used for a long period of time.

In this regard, the optical member may have a color value variation Δb* of less than 0.4, as calculated according to the following Equation 2. Within this range, the light emitting device can prevent or substantially prevent change or deterioration in screen quality, even after the optical member is used for a long period of time. For example, the optical member may have a color value variation Δb* of 0 to less than 0.4:

$${{Δ b *= \vert ( b \text{*)}}_{2} - ( b \text{*)}}_{1} \vert , \qquad Equation 2$$

where (b*) 1 is a color value b* of the optical member, and (b*) 2 is a color value b* of the optical member, as measured after a total of 21 cycles of light irradiation, each cycle being defined as irradiating the optical member with light at a wavelength of 340 nm and at an irradiance of 0.35 W/m² while the optical member is left at 25° C. for 4 hours and then left at 63° C. for 8 hours.

In one or more embodiments, in Equation 2, (b*) 1 may be 7 or less, for example, 6.8, 0 to 6.8, or 4 to 6.8.

In one or more embodiments, in Equation 2, (b*) 2 may be 7 or less, for example, 6.8, 0 to 6.8, or 4 to 6.8.

According to one or more embodiments, the optical member has excellent durability and high peel strength with respect to an optical display panel.

Herein, an optical member according to an embodiment will be described.

The optical member includes an adhesive layer and a base film stacked on a surface of the adhesive layer, wherein the adhesive layer includes a cured product of a composition including a UV absorbent and a (meth)acrylic copolymer, and wherein the optical member has a light transmittance variation ΔT of 0%, as calculated according to Equation 1, and a color value variation Δb* of less than 0.4, as calculated according to Equation 2.

The optical member may further include a release film on another surface of the adhesive layer to protect the adhesive layer.

A configuration of the optical member will now be described in further detail.

### Adhesive Layer

The adhesive layer may adhesively attach the optical member to an optical display panel. By including a cured product of a composition described below, the adhesive layer can provide an optical member having a low light transmittance variation at a wavelength of 380 nm, a low variation of color value b*, high peel strength with respect to the optical display panel, and excellent durability, even if exposed to UV light for a long period of time under repeated temperature changes between room temperature and high temperature.

In one or more embodiments, the cured product may include a thermally cured product of the composition.

The composition includes a UV absorbent and a (meth)acrylic copolymer.

In an embodiment, the UV absorbent absorbs light in a wavelength range of 360 nm to 410 nm. Absorption of light in the wavelength range of 360 nm to 410 nm can significantly prevent or substantially prevent damage to light emitting devices by external light.

In an embodiment, the UV absorbent may include an indole-based UV absorbent.

The indole-based UV absorbent has lower light transmittance, not only in a wavelength range of 360 nm to 410 nm, but also at wavelengths of 400 nm and 405 nm than other types of UV absorbents, thereby sufficiently suppressing damage to light emitting devices. In an embodiment, the optical member including the indole-based UV absorbent may have a light transmittance of 5% or less, for example, 0 to 5%, at a wavelength of 405 nm.

In addition, the indole-based UV absorbent provides a suitable range of light transmittance at wavelength of 420 nm, thereby ensuring high luminous efficacy. In an embodiment, the optical member including the indole-based UV absorbent may have a light transmittance of 25% or more, for example, 25% to 50%, at a wavelength of 420 nm.

Further, the indole-based UV absorbent provides a suitable range of light transmittance at a wavelength of 450 nm, thereby ensuring high luminous efficacy. In an embodiment, the optical member including the indole-based UV absorbent may have a light transmittance of 87% or more, for example, 87% to 90%, at a wavelength of 450 nm.

In an embodiment, the indole-based UV absorbent may include at least one of compounds represented by the Formula 1 or Formula 2:

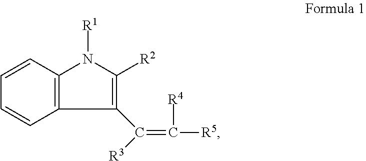

where R¹ is hydrogen or a substituted or unsubstituted C₁ to C₁₀ alkyl group, R² is hydrogen or a substituted or unsubstituted C₆ to C₂₀ aryl group, R³ is hydrogen or a substituted or unsubstituted C₁ to C₁₀ alkyl group, R⁴ is hydrogen, a cyano group (CN), or a substituted or unsubstituted C₁ to C₁₀ alkyl group, and R⁵ is a cyano group or —(C═O)O—R⁶ (R⁶ being a substituted or unsubstituted C₁ to C₁₀ alkyl group or a substituted or unsubstituted C₆ to C₂₀ aryl group;

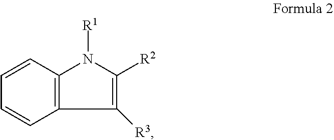

where R¹ is hydrogen or a substituted or unsubstituted C₁ to C₁₀ alkyl group, R² is hydrogen or a substituted or unsubstituted C₆ to C₂₀ aryl group, and R³ is hydrogen or a substituted or unsubstituted C₁ to C₁₀ alkyl group.

In an embodiment, R¹ is a C₁ to C₅ alkyl group, and, in an embodiment, a methyl group, R² is a C₆ to C₁₀ aryl group, and, in an embodiment, a phenyl group, R³ is a hydrogen or a C₁ to C₅ alkyl group, and, in an embodiment, hydrogen, R⁴ is a cyano group, and R⁵ is a cyano group or —(C═O)—O—R⁶ (R⁶ being a substituted or unsubstituted C₁ to C₅ alkyl group). In an embodiment, the compound represented by Formula 1 may include a compound represented by the following Formula 1-1 or a compound represented by the following Formula 1-2:

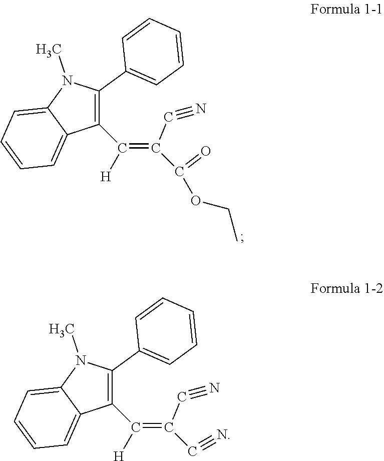 [SMILES: CCOC(=O)/C(C#N)=C/c1c(-c2ccccc2)n(C)c2ccccc12 ; Cn1c(-c2ccccc2)c(C=C(C#N)C#N)c2ccccc21]

In an embodiment, the compound of Formula 1 may have a melting point of 100° C. or more, and, in an embodiment, 140° C. to 220° C., and may be solid at room temperature. The compound of Formula 1 may be prepared by any typical synthetic method known to those skilled in the art or may be obtained from commercially available products.

In an embodiment, the compound of Formula 1 may have an absorbance of 0.8 AU or more, and, in an embodiment, 0.8 AU to 1.0 AU, at a wavelength of 390 nm for a concentration of 10 mg/L in chloroform (path 1 cm), and a maximum absorption wavelength of greater than 390 nm, and, in an embodiment, greater than 390 nm and less than or equal to 400 nm, and, in an embodiment, greater than 390 nm and less than 400 nm. Within this range, the compound of Formula 1 can sufficiently absorb external light at a wavelength of 420 nm or less, and, in an embodiment, 400 nm to 420 nm, thereby increasing stability of the light emitting devices with respect to external light through decrease in transmittance. Here, the maximum absorption wavelength refers to a wavelength exhibiting a maximum absorption peak, that is, a wavelength exhibiting a maximum absorbance in an absorbance curve according to wavelengths. The absorbance may be measured by any of typical methods known to those skilled in the art.

In an embodiment, the UV absorbent may be present in an amount of 1.25 wt % (% by weight) to 1.8 wt % in the adhesive layer. Within this range, the UV absorbent can sufficiently inhibit damage to the light emitting devices and can prevent or substantially prevent deterioration in light transmittance of the optical member due to excessive inclusion thereof. For example, the UV absorbent may be present in an amount of 1.35 wt % to 1.65 wt % in the adhesive layer.

In an embodiment, the UV absorbent may be present in an amount of 1.0 parts by weight to 5 parts by weight, for example, 1.2 parts by weight to 2.5 parts by weight, relative to 100 parts by weight of the (meth)acrylic copolymer. Within this range, a low light transmittance at a wavelength of 380 nm maybe provided and it is possible to prevent or substantially prevent the color value b* from excessively increasing due to excessive inclusion of the UV absorbent.

With the UV absorbent, the optical member can provide the aforementioned effects. However, it is confirmed that such an optical member does not secure long-term reliability of the light emitting devices due to a large light transmittance variation at a wavelength of 380 nm and a large variation of color value b* when exposed to UV light for a long period of time under repeated temperature changes between room temperature and high temperature.

It is confirmed that the (meth)acrylic copolymer described below is capable of providing a low light transmittance variation at a wavelength of 380 nm and a low variation of color value b* when an optical member including the (meth)acrylic copolymer and the UV absorbent, and, in an embodiment, an indole-based UV absorbent, is exposed to UV light for a long period of time under repeated temperature changes between room temperature and high temperature.

In an embodiment, the adhesive layer may include a pressure sensitive adhesive layer.

The (meth)acrylic copolymer may be a non-carboxylic acid copolymer free from a carboxylic acid group. The (meth)acrylic copolymer containing a carboxylic acid group may have lower durability when adhesively attached to an optical display panel.

The (meth)acrylic copolymer may be a copolymer of a monomer mixture including a (meth)acrylic monomer having a homopolymer glass transition temperature of −40° C. or less and containing an alkyl group, a monomer having a homopolymer glass transition temperature of 15° C. or more, and a (meth)acrylic monomer containing a hydroxyl group.

In an embodiment, the (meth)acrylic monomer having a homopolymer glass transition temperature of −40° C. or less and containing an alkyl group, the monomer having a homopolymer glass transition temperature of 15° C. or more, and the (meth)acrylic monomer containing a hydroxyl group may be present in a total amount of 99 mol % or more, for example, 99 mol % to 100 mol %, or 100 mol %, in the monomer mixture. Within this range, the monomer mixture can be effectively used to provide the aforementioned effects of the optical member.

The (meth)acrylic monomer having a homopolymer glass transition temperature of −40° C. or less and containing an alkyl group can increase peel strength of the adhesive layer and facilitate formation of a matrix of the adhesive layer. For example, the monomer may have a homopolymer glass transition temperature of-80° C. to −40° C.

In an embodiment, the monomer has a homopolymer glass transition temperature of −80° C. to −50° C., for example, −80° C. to −60° C. Within this range, the monomer can be effectively used to provide the aforementioned effects of the optical member when combined with the monomer having a high homopolymer glass transition temperature.

The (meth)acrylic monomer may include a (meth)acrylic acid ester containing a straight or branched C₁ to C₈ alkyl group at an ester site thereof. Herein, the carbon number refers only to the number of carbon atoms constituting a main chain of the alkyl group. In an embodiment, the carbon number is in a range from 6 to 8.

For example, the (meth)acrylic monomer may include at least one selected from among n-butyl (meth)acrylate, pentyl (meth)acrylate, hexyl (meth)acrylate, 2-ethylhexyl (meth)acrylate, heptyl (meth)acrylate, octyl (meth)acrylate, and iso-octyl (meth)acrylate, without being limited thereto. These may be used alone or as a mixture thereof. In an embodiment, the (meth)acrylic monomer includes 2-ethylhexyl (meth)acrylate.

In an embodiment, the (meth)acrylic monomer may be present in an amount of 65 mol % to 90 mol %, for example, 70 mol % to 90 mol %, or 70 mol % to 85 mol %, in the monomer mixture. Within this range, the adhesive layer can have increased peel strength.

The monomer having a homopolymer glass transition temperature of 15° C. or more may provide the aforementioned effects of the optical member. The monomer having a homopolymer glass transition temperature of less than 15° C. can cause deterioration in optical properties in solar testing and problems including a high light transmittance variation at a wavelength of 380 nm and a high variation of color value b* if the optical member is exposed to UV light for a long period of time under repeated temperature changes between room temperature and high temperature.

In an embodiment, the monomer has a homopolymer glass transition temperature of 15° C. to 260° C., for example, 19° C. to 250° C. Within this range, the monomer can be effectively used to provide the aforementioned effects of the optical member when combined with the monomer having a low homopolymer glass transition temperature.

The monomer may include at least one of a (meth)acrylic acid ester containing an alkyl or alicyclic group at an ester site thereof or a maleimide containing an alicyclic or aromatic group.

In an embodiment, the ester containing an alkyl group is t-butyl (meth)acrylate or vinyl acetate. In an embodiment, the ester containing an alicyclic group includes at least one selected from among isobornyl (meth)acrylate, cyclohexyl (meth)acrylate, and dicyclopentadienyl (meth)acrylate. In an embodiment, the maleimide containing an alicyclic group is n-cyclohexyl maleimide. In an embodiment, the maleimide containing an aromatic group is N-phenylmaleimide or 2-methyl-N-phenylmaleimide.

In an embodiment, the monomer may be present in an amount of 5 mol % to 40 mol %, for example, 10 mol % to 30 mol %, 10 mol % to 27 mol %, or 15 mol % to 30 mol %, in the monomer mixture. Within this range, the optical member can satisfy the respective values of Equation 1 and Equation 2 without impairing high peel strength of the adhesive layer.

The (meth)acrylic monomer containing a hydroxyl group can increase peel strength of the adhesive layer by reacting with a curing agent. The (meth)acrylic monomer containing a hydroxyl group is a (meth)acrylic acid ester containing a hydroxyl group, which may include a (meth)acrylic acid ester containing a C₁ to C₂₀ alkyl group having at least one hydroxyl group at an ester site thereof. For example, the (meth)acrylic monomer containing a hydroxyl group may include at least one selected from among 2-hydroxyethyl (meth)acrylate, 2-hydroxypropyl (meth)acrylate, 2-hydroxybutyl (meth)acrylate, 4-hydroxybutyl (meth)acrylate, 6-hydroxyhexyl (meth)acrylate, 1-chloro-2-hydroxypropyl (meth)acrylate, and 1-chloro-2-hydroxypropyl (meth)acrylate. These may be used alone or as a mixture thereof.

In an embodiment, the (meth)acrylic monomer containing a hydroxyl group may be present in an amount of 0.1 mol % to 5 mol %, for example 0.5 mol % to 3 mol %, or 0.5 mol % to 2 mol %, in the monomer mixture. Within this range, the adhesive layer can maintain mechanical strength and the optical member can reach the respective values of Equation 1 and Equation 2.

The monomer mixture may be free from a (meth)acrylic acid ester containing a long-chain alkyl group. The presence of the (meth)acrylic acid ester containing a long chain alkyl group can results in unsuitable cohesion and adhesion of the adhesive layer. The (meth)acrylic acid ester containing a long-chain alkyl group may refer to a (meth)acrylic acid ester containing a C₁₀ to C₂₅ alkyl group. Herein, the carbon number refers only to the number of carbon atoms constituting a main chain of the long-chain alkyl group.

In an embodiment, the (meth)acrylic copolymer may have a glass transition temperature of −60° C. to −10° C., for example, −60° C. to −30° C., −60° C. to −40° C., or −60° C. to −50° C. Within these ranges, the (meth)acrylic copolymer can be effectively used to provide the effects of the optical members.

In an embodiment, the (meth)acrylic copolymer may have a weight average molecular weight of 500,000 g/mol to 1,500,000 g/mol, for example, 500,000 g/mol to 1,000,000 g/mol, or 600,000 g/mol to 1,000,000 g/mol. Within this range, the (meth)acrylic copolymer can be effectively used to provide the effects of the optical member.

The (meth)acrylic copolymer may be prepared by polymerizing the monomer mixture by any typical polymerization methods. The polymerization method may include any of typical methods known to those skilled in the art. For example, the (meth)acrylic copolymer may be prepared by adding an initiator to the monomer mixture, followed by any typical copolymerization, such as suspension polymerization, emulsion polymerization, solution polymerization, and the like. In an embodiment, polymerization may be performed at a temperature of 65° C. to 70° C. for 6 hours to 8 hours. The initiator may be selected from any typical initiators including azo-based polymerization initiators; and/or peroxides, such as benzoyl peroxide or acetyl peroxide.

The composition may further include a curing agent.

The curing agent may react with the (meth)acrylic copolymer to provide peel strength.

The curing agent may include a heat curing agent. The heat curing agent can facilitate formation of the adhesive layer from an adhesive layer composition including a UV absorbent.

In an embodiment, the curing agent may be present in an amount of 0.1 parts by weight to 5 parts by weight, for example, 0.05 parts by weight to 2.5 parts by weight, relative to 100 parts by weight of the (meth)acrylic copolymer. Within this range, the curing agent allows the composition to provide adhesion through crosslinking of the composition and can prevent or substantially prevent deterioration in transparency due to excessive use thereof.

The heat curing agent may include at least one selected from among an isocyanate curing agent, a metal chelate curing agent, an epoxy curing agent, an aziridine curing agent, an amine curing agent, and a heat polymerization initiator. For example, the heat curing agent may include at least one of an isocyanate curing agent or a metal chelate curing agent. These may be used alone or as a mixture thereof.

The isocyanate curing agent may include a bi- or higher functional isocyanate curing agent, for example, a bi- to hexa-functional isocyanate curing agent, and may include at least one selected from among xylene diisocyanate (XDI) including m-xylene diisocyanate and the like, methylenebis(phenyl isocyanate) (MDI) including 4,4′-methylenebis(phenyl isocyanate) and the like, naphthalene diisocyanate, toluene diisocyanate, hexamethylene diisocyanate, and isophorone diisocyanate, or adducts thereof, without being limited thereto.

The metal chelate curing agent may include a coordination compound of a polyvalent metal, for example, aluminum. For example, the metal chelate curing agent may include aluminum chelating compounds, such as aluminum trisethylacetoacetate, aluminum ethyl acetoacetate diisopropylate, aluminum trisacetylacetonate, and the like.

The composition may further include a solvent. The solvent can increase coating properties of the composition. The solvent may include typical types of solvents known to those skilled in the art. For example, the solvent may include at least one selected from among methyl ethyl ketone, ethyl acetate, and toluene.

The composition may further include at least one selected from among a silane coupling agent, a reworking agent, a curing catalyst, an antistatic agent, and a curing catalyst.

The silane coupling agent can realize an adhesive layer with high adhesion to an adherend, such as glass. The silane coupling agent may include any typical silane coupling agents known to those skilled in the art. For example, the silane coupling agent may include at least one selected from the group consisting of a silicon compound having an epoxy structure, such as 3-glycidoxypropyltrimethoxysilane, 3-glycidoxypropylmethyldimethoxysilane, and 2-(3,4-epoxycyclohexyl)ethyltrimethoxysilane; a polymerizable unsaturated group-containing silicon compound, such as vinyltrimethoxysilane, vinyltriethoxysilane, and (meth)acryloxypropyltrimethoxysilane; an amino group-containing silicon compound, such as 3-aminopropyltrimethoxysilane, n-(2-aminoethyl)-3-aminopropyltrimethoxysilane, and n-(2-aminoethyl)-3-aminopropylmethyldimethoxysilane; and 3-chloropropyltrimethoxysilane, without being limited thereto. In an embodiment, the silane coupling agent may be present in an amount of 0.001 parts by weight to 5 parts by weight, and, in an embodiment, 0.001 parts by weight to 3 parts by weight, relative to 100 parts by weight of the (meth)acrylic copolymer. Within this range, the silane coupling agent can ensure good durability of the adhesive layer while reducing changes in composition and properties of the adhesive layer over time.

The reworking agent improves reworkability of the adhesive layer and may include a polysiloxane oligomer or a mixture including the polysiloxane oligomer. In an embodiment, the reworking agent may be present in an amount of 0.001 parts by weight to 5 parts by weight, and, in an embodiment, 0.005 parts by weight to 1 part by weight, relative to 100 parts by weight of the (meth)acrylic copolymer. Within this range, the reworking agent can improve reworkability of the adhesive layer without affecting the properties of the adhesive layer.

The antistatic agent inhibits generation of static electricity during reworking of the adhesive layer and may include any typical antistatic agents known in the art. In an embodiment, the antistatic agent may be present in an amount of 0.001 parts by weight to 5 parts by weight, and, in an embodiment, 0.1 parts by weight to 5 parts by weight, relative to 100 parts by weight of the (meth)acrylic copolymer. Within this range, the antistatic agent can provide antistatic properties without affecting the properties of the adhesive layer.

The curing catalyst may include at least one selected from among a boron compound, for example, a boron trifluoride complex, and, in an embodiment, an etherate of boron trifluoride, a tetrahydrofuran complex of boron trifluoride (BF₃-THF), or an aniline complex of boron trifluoride (BF₃-aniline), and, in an embodiment, BF₃·O(CH₃)₂ (boron trifluoride dimethyl etherate) or BF₃·O(C₂H₅)₂ (boron trifluoride diethyl etherate); a phosphine compound, for example, triphenylphosphine, tributylphosphine, tri(p-methylphenyl)phosphine, tri(nonylphenyl)phosphine, triphenylphosphine-triphenylborate, triphenylphosphine-tetraphenylborate, and the like; a secondary amine or tertiary amine compound, for example, an α-tertiary amine compound (for example, KH-30, Kukdo Chemical Co., Ltd.), such as triethylamine, benzydiethylamine, or benzydimethylamine; an imidazole compound, for example, 2-methylimidazole, 2-phenylimidazole, 2-phenyl-4-methylimidazole, and the like; and a sulfonic acid compound, for example, paratoluene sulfonic acid, dodecyl benzene sulfonic acid, naphthalene sulfonic acid, naphthalene disulfonic acid, methane sulfonic acid, methane disulfonic acid, phenol sulfonic acid, dibutyltin dilaurate and the like. In an embodiment, the curing catalyst may be present in an amount of 0.01 parts by weight to 5 parts by weight, and, in an embodiment, 0.05 parts by weight to 2 parts by weight, relative to 100 parts by weight of the (meth)acrylic copolymer. Within this range, the curing catalyst can shorten the curing time.

The composition may further include typical additives. The additives may include any of an antioxidant, an adhesion imparting resin, a plasticizer, and the like. In an embodiment, the additives may be present in an amount of 0.001 parts by weight to 5 parts by weight, and, in an embodiment, 0.01 parts by weight to 1 part by weight, relative to 100 parts by weight of the (meth)acrylic copolymer. Within this range, the additives can provide inherent effects thereof without impairing the properties of the adhesive layer.

In an embodiment, the composition may have a viscosity of 1,000 cP to 4,000 cP at 25° C. Within this range, the composition provides for adjustment of the thickness of the adhesive layer, can ensure that the adhesive layer is free from stains, and can ensure an even coating surface.

In an embodiment, the adhesive layer may have a thickness of 100 μm or less, and, in an embodiment, 5 μm to 50 μm. Within this range, the adhesive layer can be used in an optical display apparatus.

In an embodiment, the adhesive layer may be formed by coating the composition to a thickness (e.g., a predetermined thickness), drying the coated composition, and aging the dried composition under constant temperature/humidity conditions at a temperature of 25° C. to 35° C. and a relative humidity of 30% to 60%, without being limited thereto.

### Base Film

The base film may be formed on the adhesive layer to protect the adhesive layer and to improve mechanical strength of the optical member. In an embodiment, the base film may be directly formed on the adhesive layer. Herein, “directly formed” means that no other adhesive layer or bonding layer is interposed between the base film and the adhesive layer.

In an embodiment, the base film may have a light transmittance of 80% or more, for example, 88% to 99%, at a wavelength of 270 nm to 800 nm. Within this range, the base film can enhance luminous efficacy without affecting an optical path of external light or internal light transmitted through the optical member.

In an embodiment, the base film may have a light transmittance of 1% or less, for example, 0.01% to 0.05%, at a wavelength of 380 nm.

In an embodiment, the base film may have a color value b* of 4.0 to 8.0, for example, 4.5 to 7.0. Within this range, the base film does not affect the color value b* of the optical member.

The base film may include at least one of an optically transparent protective film or an optically transparent protective coating layer.

If the base film is of the protective film type, the base film may include a protective film formed of an optically clear resin. The protective film may be formed by melt extrusion of the resin. In an embodiment, the resin may be further subjected to a stretching process. The resin may include at least one selected from among cellulose ester resins including triacetylcellulose and the like, cyclic polyolefin resins including an amorphous cyclic olefin polymer (COP) and the like, polycarbonate resins, polyester resins, such as polyethylene terephthalate (PET) and the like, polyether sulfone resins, polysulfone resins, polyamide resins, polyimide resins, non-cyclic polyolefin resin, poly(meth)acrylate resins, such as poly(methyl methacrylate) and the like, polyvinyl alcohol resins, polyvinyl chloride resins, and polyvinylidene chloride resins.

If the base film is of the protective coating layer type, the base film can have good properties in terms of adhesion to the adhesive layer, transparency, mechanical strength, thermal stability, moisture barrier capacity, and durability. In an embodiment, the protective coating layer as the base film may be formed of an actinic radiation-curable resin composition including an actinic radiation-curable compound and a polymerization initiator.

The actinic radiation-curable compound may include at least one selected from among a cationic polymerizable curable compound, a radical polymerizable curable compound, a urethane resin, and a silicone resin. The cationic polymerizable curable compound may be an epoxy compound having at least one epoxy group therein or an oxetane compound having at least one oxetane ring therein. The radical polymerizable curable compound may be a (meth)acrylic compound having at least one (meth)acryloyloxy group therein.

In an embodiment, the base film may have a thickness of 5 μm to 200 μm, and, in an embodiment, 30 μm to 120 μm, and, in an embodiment, 50 μm to 100 μm (for the protective film type) or 5 μm to 50 μm (for the protective coating layer type). Within this range, the base film can be used in an optical display apparatus.

The optical member may further include a functional coating layer, for example, a hard coating layer, a moisture-resistant layer, an anti-reflective layer, or the like, on the other surface of the base film.

In accordance with another aspect of embodiments of the present invention, an optical display apparatus is provided.

The optical display apparatus includes the optical member according to an embodiment of the present invention.

The optical display apparatus includes the optical member described above.

In an embodiment, the optical display apparatus may include a panel for an optical display apparatus and the optical member stacked on the panel.

In an embodiment, the optical display apparatus is free from a polarizing plate. With the optical member capable of replacing a function of the polarizing plate, the optical display apparatus can prevent or substantially prevent damage to a light emitting device, despite the absence of the polarizing plate.

The optical display apparatus may include a liquid crystal display, a light emitting device display, such as an organic light emitting display, or the like, without being limited thereto.

Next, the present invention will be described in further detail with reference to some examples. However, these examples are provided for illustration and are not to be construed in any way as limiting the present invention.

### Preparative Example 1: Preparation of (meth)acrylic Copolymer

Ethyl acetate and/or methyl ethyl ketone or toluene were added to a 1 L reactor configured to allow reflux under nitrogen gas and provided with a cooling device to facilitate temperature control. 100 parts by weight of a monomer mixture including 79 mol % of 2-ethylhexyl acrylate (2-EHA), 20 mol % of isobornyl acrylate (IBXA) and 1 mol % of 4-hydroxybutyl acrylate (4-HBA) was added to the reactor. Nitrogen gas was added to the reactor for 30 minutes to remove oxygen from the monomer mixture by replacing oxygen in the reactor, and the inner temperature of the reactor was maintained at 60° C. After the monomer mixture was uniformly stirred, 0.06 parts by weight of V601 (dimethyl 2,2′-azobis(2-methylpropionate)) was added as an initiator and reacted for 4 hours. The inner temperature of the reactor was increased to 65° C., followed by adding the initiator again to the reactor. After further reaction at 65° C. for 2 hours, the reactor was cooled to room temperature, followed by adding methyl ethyl ketone to the resulting mixture, thereby preparing a solution containing 25 wt % of a (meth)acrylic copolymer. The weight average molecular weight and glass transition temperature of the prepared (meth)acrylic copolymer were obtained by GPC and DSC analysis.

### Preparative Examples 2 to 10: Preparation of (meth)acrylic Copolymer

(Meth)acrylic copolymers were prepared in the same manner as in Preparative Example 1 except that the type and content of each monomer in the monomer mixture were changed as listed in Table 1 and the content of the initiator or reaction time was changed. In Table 1, “-” means that the content of a corresponding component is 0 mol %.

TABLE 1

| Preparative | | | | | | | | | | | | | |
|---|---|---|---|---|---|---|---|---|---|---|---|---|---|
| Example | 2-EHA | MA | IBXA | t-BA | CHA | DCPA | PMI | N-CMI | BzA | LA | 4-HBA | Mw | Tg |
| 1 | 79 | — | 20 | — | — | — | — | — | — | — | 1 | 595291 | −54.4 |
| 2 | 74 | — | — | 25 | — | — | — | — | — | — | 1 | 727398 | −54.1 |
| 3 | 72 | — | — | — | 27 | — | — | — | — | — | 1 | 796032 | −54.5 |
| 4 | 79 | — | — | — | — | 20 | — | — | — | — | 1 | 824089 | −52.7 |
| 5 | 83 | — | — | — | — | — | 16 | — | — | — | 1 | 665306 | −53.3 |
| 6 | 83 | — | — | — | — | — | — | 16 | — | — | 1 | 552521 | −54.6 |
| 7 | 67 | 26 | — | — | — | — | — | — | — | — | 7 | 882514 | −51.3 |
| 8 | 63 | 22 | — | — | — | — | — | — | — | — | 15 | 936042 | −50.2 |
| 9 | 74 | — | — | — | — | — | — | — | 25 | — | 1 | 582284 | −55.2 |
| 10 | 74 | — | — | — | — | — | — | — | — | 25 | 1 | 567521 | −78.5 |

*In Table 1,
2-EHA: 2-ethylhexyl acrylate (Tg of homopolymer: −65° C.)
MA: Methyl acrylate (Tg of homopolymer: 8° C.)
IBXA: Isobornyl acrylate (Tg of homopolymer: 94° C.)
t-BA: t-butyl acrylate (Tg of homopolymer: 41° C.)
CHA: Cyclohexyl acrylate (Tg of homopolymer: 19° C.)
DCPA: Dicyclopentadienyl acrylate (Tg of homopolymer: 120° C.)
PMI: Phenylmaleimide (Tg of homopolymer: 250° C.)
N-CMI: N-cyclohexyl maleimide (Tg of homopolymer: 210° C.)
BzA: Benzyl acrylate (Tg of homopolymer: 8° C.)
LA: Lauryl acrylate (Tg of homopolymer: −30° C.)
4-HBA: 4-hydroxybutyl acrylate (Tg of homopolymer: −30° C.)
Mw: Weight average molecular weight of acrylic copolymer (unit: g/mol)
Tg: Glass transition temperature of acrylic copolymer (unit: ° C.).

Details of components used in the Examples and Comparative Examples are as follows.

(A) (Meth)acrylic copolymer

The (meth)acrylic copolymer prepared in Preparative Example in Table 1 and other (meth)acrylic copolymers

(B) Curing agent: Xylene diisocyanate adduct of trimethylolpropane (isocyanate curing agent, TD-75, Soken)

(C) Curing catalyst: DBTDL (dibutyltin dilaurate) catalyst

(D) NUV-absorbent: 2-phenyl-n-methylindole (Bonasorb® UA-3912, Orient, Japan)

### Example 1

In terms of solid content, 100 parts by weight of the (meth)acrylic copolymer of Preparative Example 1, 0.09 parts by weight of the isocyanate curing agent (B), 0.0035 parts by weight of the curing catalyst (C), and 1.45 parts by weight of the NUV-absorbent (D) were mixed to prepare a mixture, which in turn was mixed with methyl ethyl ketone as a solvent added in an amount of 4 times the weight of the (meth)acrylic copolymer of Preparative Example 1. Then, the prepared composition was mixed in a mechanical reactor, stirred at room temperature for 20 minutes, and flushed with nitrogen gas for 30 minutes, thereby preparing an adhesive layer composition.

The adhesive layer composition was deposited to a predetermined thickness on one surface of a release film (subjected to silicone treatment, thickness: 38 μm), dried at 100° C. for 4 minutes to prepare a coat (thickness: 23 μm) and a triacetylcellulose film (light transmittance at a wavelength of 270 nm to 800 nm: 96.87%, b* value: 0.43, thickness: 40 μm) was placed on the coat. Then, the resulting product was left at 35° C. and 45% RH for 2 days, thereby preparing an adhesive layer-containing sheet including the release film (thickness: 38 μm), the adhesive layer (thickness: 23 μm) and the TAC film (thickness: 40 μm) sequentially stacked in the stated order.

### Examples 2 to 6

Adhesive layer-containing sheets each including a release film, an adhesive layer and a TAC film sequentially stacked in the stated order were prepared in the same manner except that the type of (meth)acrylic copolymer was changed as listed in Table 2.

### Comparative Example 1

The same release film (subjected to silicone treatment, thickness: 38 μm) and the same triacetylcellulose film (light transmittance at a wavelength of 270 nm to 800 nm: 96.87%, b* value: 0.43, thickness: 40 μm) as in Example 1 were used. As an adhesive layer, a 15 μm thick cured product of a composition including a (meth)acrylic copolymer and a curing agent was used. As a hard coating layer, an 8 μm thick layer including an acrylic resin and 2-phenyl-n-methylindole was used. A sheet including the adhesive layer, the triacetylcellulose film, and the hard coating layer sequentially stacked on a release film was prepared.

### Comparative Examples 2 to 8

Adhesive layer-containing sheets each including a release film, an adhesive layer and a TAC film sequentially stacked in the stated order were prepared in the same manner except that the type of (meth)acrylic copolymer was changed as listed in Table 3.

The adhesive layer-containing sheets prepared in the Examples and Comparative Examples were evaluated as to properties listed in Table 2, and evaluation results are shown in Table 2 and Table 3.

(1) Peel Strength (Unit: Gf/Inch) with Respect to Alkali-Free Glass Plate:

The prepared adhesive layer-containing sheet was cut to a size of 25 mm×25 mm×200 mm and the release film was removed therefrom, followed by attaching the sheet to an alkali-free glass plate via the adhesive layer. A resulting product was left at room temperature for 30 minutes to prepare a specimen for measurement of peel strength. Peel strength of the adhesive layer was measured upon peeling the entirety of the adhesive layer and the TAC film off of the alkali-free glass plate using a peel strength tester (TA Instrument) at a peeling speed of 300 mm/see, a peeling angle of 180°, and a peeling temperature of 25° C. Measurement was performed three times and an average value was obtained.

### (2) Solar Test:

The prepared adhesive layer-containing sheet was cut to a size of 25 mm×200 mm (width×length) and attached to a glass plate, thereby preparing a specimen. UV spectra (light transmittance T₁ and (b*)₁) at a wavelength of 270 nm to 800 nm were measured with respect to the prepared specimen using a UV/Vis Spectrophotometer (Jasco V-650).

Next, the specimen was placed in a UV chamber and irradiated with UV light at a wavelength of 340 nm under the following conditions.

Solar test conditions: A total of 21 cycles of light irradiation (252 hours in total), in which each cycle included irradiating the specimen with UV light at a wavelength of 340 nm and at an irradiance of 0.35 W/m² while leaving the specimen at 25° C. for 4 hours and then left at 63° C. for 8 hours.

Thereafter, the specimen was removed from the UV chamber and then left at room temperature for 30 minutes, followed by measuring UV spectra (light transmittance T₂ and (b*)₂ values) in the same manner as above. A difference ΔT in light transmittance and a difference Δb* in color values b* before and after the solar test were calculated.

(3) Durability: Specimens were prepared by cutting the prepared adhesive layer-containing sheet to a size of 25 mm×25 mm×200 mm and removing the release film therefrom, followed by attaching the sheet to an alkali-free glass plate. The prepared specimens were subjected to four different conditions, that is, a condition in which the specimen was left at 85° C. for 500 hours, a condition in which the specimen was left at 85° C. and 85% RH for 500 hours, a condition in which the specimen was left at 60° C. and 95% RH for 500 hours, or a condition in which the specimen was subjected to 50 cycles of being left at −40° C. for 5 hours and then left at 85° C. for 5 hours. No change, such as bubbles, lifting or discoloration, at an interface between the adhesive layer and the glass plate and at an interface between the adhesive layer and the TAC film was evaluated as o, and any change at the interfaces was evaluated as x.

TABLE 2

| | Light | Example 1 | Example 2 | Example 3 | Example 4 | Example 5 | Example 6 |
|---|---|---|---|---|---|---|---|
| | transmittance | Preparative | Preparative | Preparative | Preparative | Preparative | Preparative |
| Property | or b* value | Example 1 | Example 2 | Example 3 | Example 4 | Example 5 | Example 6 |
| @0 | T₁@450 | 89.8 | 89.8 | 89.2 | 89.6 | 89.3 | 88.9 |
| cycles | nm | | | | | | |
| | T₁@420 | 45.2 | 45.6 | 41.9 | 43.4 | 29.1 | 42.7 |
| | nm | | | | | | |
| | T₁@405 | 2.3 | 2.4 | 1.8 | 2.1 | 0.8 | 2.4 |
| | nm | | | | | | |
| | T₁@380 | 0.04 | 0.04 | 0.04 | 0.04 | 0.03 | 0.04 |
| | nm | | | | | | |
| | (b*)₁ | 4.71 | 4.65 | 4.98 | 4.87 | 6.80 | 4.99 |
| @21 | T₂@450 | 89.5 | 89.7 | 89.3 | 89.7 | 88.4 | 88.4 |
| cycles | nm | | | | | | |
| | T₂@420 | 46.3 | 47.4 | 44.1 | 44.9 | 30.5 | 43.8 |
| | nm | | | | | | |
| | T₂@405 | 3.2 | 4.3 | 3.3 | 3.4 | 2.4 | 3.2 |
| | nm | | | | | | |
| | T₂@380 | 0.04 | 0.04 | 0.04 | 0.04 | 0.03 | 0.04 |
| | nm | | | | | | |
| | (b*)₂ | 4.57 | 4.55 | 5.22 | 5.04 | 6.57 | 5.00 |
| ΔT | @450 nm | −0.3 | −0.2 | 0.0 | 0.1 | −0.9 | −0.5 |
| Δb | @420 nm | 1.1 | 1.8 | 2.2 | 1.5 | 1.4 | 1.1 |
| | @405 nm | 0.9 | 1.9 | 1.5 | 1.3 | 1.6 | 0.8 |
| | @380 nm | 0.00 | 0.00 | 0.00 | 0.00 | 0.00 | 0.00 |
| | b* | −0.14 | −0.10 | 0.24 | 0.17 | −0.23 | 0.01 |

| | | | | | | |
|---|---|---|---|---|---|---|
| Durability | ◯ | ◯ | ◯ | ◯ | ◯ | ◯ |
| Peel strength | 512 | 565 | 552 | 489 | 505 | 540 |

TABLE 3

| | | Comparative | | | | Comparative | Comparative | Comparative | Comparative |
|---|---|---|---|---|---|---|---|---|---|
| | Light | Example 1 | Comparative | Comparative | Comparative | Example 5 | Example 6 | Example 7 | Example 8 |
| | transmittance | Preparative | Example 2 | Example 3 | Example 4 | Preparative | Preparative | Preparative | Preparative |
| Property | or b* value | Example 1 | CI-205 | PL-8540 | CI-247 | Example 7 | Example 8 | Example 9 | Example 10 |
| @ 0 | T₁@450 | 87.6 | 90.1 | 90.2 | 90.2 | 89.4 | 90.0 | 89.0 | 88.7 |
| cycles | nm | | | | | | | | |
| | T₁@420 | 34.6 | 35.1 | 36.8 | 35.3 | 33.1 | 38.2 | 42.3 | 41.8 |
| | nm | | | | | | | | |
| | T₁@405 | 1.0 | 1.0 | 1.4 | 1.0 | 1.0 | 1.3 | 2.4 | 2.2 |
| | nm | | | | | | | | |
| | T₁@380 | 0.03 | 0.04 | 0.04 | 0.04 | −0.30 | −0.30 | 0.04 | 0.04 |
| | nm | | | | | | | | |
| | (b*)₁ | 6.5 | 6.5 | 6.3 | 5.8 | 5.6 | 5.5 | 6.59 | 5.81 |
| @ 21 | T₂@450 | 86.3 | 87.9 | 89.2 | 87.7 | 88.5 | 84.8 | 88.4 | 88.4 |
| cycles | nm | | | | | | | | |
| | T₂@420 | 44.0 | 29.5 | 32.6 | 37.1 | 44.0 | 76.0 | 47.4 | 44.9 |
| | nm | | | | | | | | |
| | T₂@405 | 3.9 | 1.8 | 3.7 | 2.7 | 6.1 | 55.9 | 5.2 | 4.6 |
| | nm | | | | | | | | |
| | T₂@380 | 0.03 | 0.03 | 0.04 | 0.06 | 0.56 | 3.09 | 0.04 | 0.04 |
| | nm | | | | | | | | |
| | (b*)₂ | 6.4 | 6.9 | 6.8 | 6.6 | 7.2 | 6.6 | 8.22 | 7.05 |
| ΔT | @450 | −1.2 | −2.2 | −1.0 | −2.5 | −0.9 | −5.2 | −0.6 | −0.3 |
| Δb | nm | | | | | | | | |
| | @420 | 9.4 | −5.6 | −4.2 | 1.8 | 10.9 | 37.8 | 5.1 | 3.1 |
| | nm | | | | | | | | |
| | @405 | 2.9 | 0.8 | 2.3 | 1.7 | 5.2 | 54.7 | 2.8 | 2.4 |
| | nm | | | | | | | | |
| | @380 | 0.00 | 0.00 | 0.00 | 0.02 | 0.86 | 3.39 | 0.00 | 0.00 |
| | nm | | | | | | | | |
| | b* | −0.15 | 0.40 | 0.46 | 0.80 | 1.52 | 1.06 | 1.63 | 1.24 |

| | | | | | | | | |
|---|---|---|---|---|---|---|---|---|
| Durability | X | X | X | ◯ | ◯ | ◯ | ◯ | X |
| Peel strength | 800 | 557 | 850 | 210 | 525 | 583 | 210 | 115 |

*In Table 3,
CI-205: Acrylic binder containing carboxylic acid group (Soken Co., Ltd.)
PL-8540: Acrylic binder containing carboxylic acid group (Saiden Co., Ltd.)
CI-247: Acrylic binder free from carboxylic acid group (Soken Co., Ltd.)

As shown in Table 2, the optical members according to the present invention had a low light transmittance variation at a wavelength of 380 nm even when exposed to UV light for a long period of time under repeated temperature changes between room temperature and high temperature. The optical members according to the present invention had a low variation of color value b* even after long-term exposure to UV light under repeated temperature changes between room temperature and high temperature. The optical members according to the present invention had excellent durability and high peel strength with respect to an optical display panel.

However, as shown in Table 3, the optical members of the Comparative Examples failed to provide the effects of the present invention.

It is to be understood that various modifications, changes, alterations, and equivalent embodiments may be made by those skilled in the art without departing from the spirit and scope of the invention.

What is claimed is:

1. An optical member comprising an adhesive layer and a base film stacked on a surface of the adhesive layer,
wherein the adhesive layer comprises a cured product of a composition comprising a UV absorbent and a (meth)acrylic copolymer, and
wherein the optical member has a light transmittance variation ΔT of 0%, as calculated according to the following Equation 1, and a color value variation Δb* of less than 0.4, as calculated according to the following Equation 2:
$$Δ T = \vert {T}_{2} - {T}_{1} \vert , \qquad Equation 1$$
where T₁ is light transmittance (unit: %) of the optical member, as measured at a wavelength of 380 nm, and T₂ is light transmittance (unit: %) of the optical member, as measured at a wavelength of 380 nm after a total of 21 cycles of light irradiation, each of the cycles being defined as irradiating the optical member with light at a wavelength of 340 nm and at an irradiance of 0.35 W/m² while the optical member is left at 25° C. for 4 hours and then left at 63° C. for 8 hours;
$$Δ b *= \vert ( {b}_{2}^{⋆} ) - ( {b}_{1}^{⋆} ) \vert , \qquad Equation 2$$
where (b*1) is a color value b* of the optical member, and (b*2) is a color value b* of the optical member, as measured after a total of 21 cycles of light irradiation, each of the cycles being defined as irradiating the optical member with light at a wavelength of 340 nm and at an irradiance of 0.35 W/m² while the optical member is left at 25° C. for 4 hours and then left at 63° C. for 8 hours.

2. The optical member as claimed in claim 1, wherein the UV absorbent comprises an indole-based UV absorbent.

3. The optical member as claimed in claim 2, wherein the indole-based UV absorbent comprises at least one of compounds represented by the following Formula 1 or Formula 2: 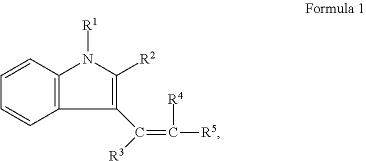
where R¹ is hydrogen or a substituted or unsubstituted C₁ to C₁₀ alkyl group, R² is hydrogen or a substituted or unsubstituted C₆ to C₂₀ aryl group, R³ is hydrogen or a substituted or unsubstituted C₁ to C₁₀ alkyl group, R⁴ is hydrogen, a cyano group (CN), or a substituted or unsubstituted C₁ to C₁₀ alkyl group, and R⁵ is a cyano group or —(C═O)O—R⁶ (R⁶ being a substituted or unsubstituted C₁ to C₁₀ alkyl group or a substituted or unsubstituted C₆ to C₂₀ aryl group; 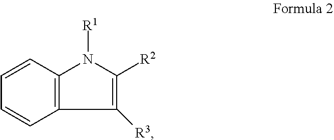
where R¹ is hydrogen or a substituted or unsubstituted C₁ to C₁₀ alkyl group, R² is hydrogen or a substituted or unsubstituted C₆ to C₂₀ aryl group, and R³ is hydrogen or a substituted or unsubstituted C₁ to C₁₀ alkyl group.

4. The optical member as claimed in claim 1, wherein the UV absorbent is present in an amount of 1.25 wt % to 1.8 wt % in the adhesive layer.

5. The optical member as claimed in claim 1, wherein the (meth)acrylic copolymer comprises a non-carboxylic copolymer free from a carboxylic acid group.

6. The optical member as claimed in claim 1, wherein the (meth)acrylic copolymer comprises a copolymer of a monomer mixture comprising a (meth)acrylic monomer having a homopolymer glass transition temperature of −40° C. or less and containing an alkyl group, a monomer having a homopolymer glass transition temperature of 15° C. or more, and a (meth)acrylic monomer containing a hydroxyl group.

7. The optical member as claimed in claim 6, wherein the monomer having a homopolymer glass transition temperature of 15° C. or more comprises at least one of a (meth)acrylic acid ester containing an alkyl group or an alicyclic group at an ester site thereof or a maleimide containing an alicyclic group or an aromatic group.

8. The optical member as claimed in claim 7, wherein the monomer having a homopolymer glass transition temperature of 15° C. or more comprises at least one selected from among t-butyl (meth)acrylate, isobornyl (meth)acrylate, cyclohexyl (meth)acrylate, dicyclopentadienyl (meth)acrylate, N-cyclohexyl maleimide, and N-phenyl maleimide.

9. The optical member as claimed in claim 6, wherein the (meth)acrylic monomer having a homopolymer glass transition temperature of −40° C. or less and containing an alkyl group comprises a (meth)acrylic acid ester containing a straight or branched C₁ to C₈ alkyl group at an ester site thereof.

10. The optical member as claimed in claim 6, wherein the (meth)acrylic monomer having a homopolymer glass transition temperature of −40° C. or less and containing an alkyl group, the monomer having a homopolymer glass transition temperature of 15° C. or more, and the (meth)acrylic monomer containing a hydroxyl group are present in a total amount of 99 mol % or more in the monomer mixture.

11. The optical member as claimed in claim 6, wherein the monomer mixture comprises:
65 mol % to 90 mol % of the (meth)acrylic monomer having a homopolymer glass transition temperature of −40° C. or less and containing an alkyl group;
5 mol % to 30 mol % of the monomer having a homopolymer glass transition temperature of 15° C. or more; and
0.1 mol % to 5 mol % of the (meth)acrylic monomer containing a hydroxyl group.

12. The optical member as claimed in claim 1, wherein the composition further comprises a curing agent.

13. The optical member as claimed in claim 1, wherein the adhesive layer has a peel strength of 300 gf/inch or more with respect to a glass plate.

14. An optical display apparatus comprising the optical member as claimed in claim 1.

15. The optical display apparatus as claimed in claim 14, wherein the optical display apparatus is free from a polarizing plate.
